(19) United States
(12) Patent Application Publication
(10) Pub. No.: US 2022/0109284 A1
(43) Pub. Date: Apr. 7, 2022

(54) DIRECT MODULATION LASER WITH HIGH POWER

(71) Applicant: Nippon Telegraph and Telephone Corporation, Tokyo (JP)

(72) Inventors: Meishin Chin, Musashino-shi, Tokyo (JP); Takahiko Shindo, Musashino-shi, Tokyo (JP)

(21) Appl. No.: 17/428,873

(22) PCT Filed: Feb. 7, 2020
(86) PCT No.: PCT/JP2020/004953

§ 371 Date: Aug. 5, 2021

(30) Foreign Application Priority Data
Feb. 12, 2019 (JP) 2019-022599

(51) Int. Cl. H01S 5/042; H01S 5/026; H01S 5/343

(52) U.S. Cl. CPC H01S 5/0427; H01S 5/12; H01S 5/343; H01S 5/0265

(57) ABSTRACT

There is provided a high-power directly modulated laser in which oscillation of an SOA unit is suppressed. The high-power directly modulated laser includes a directly modulated laser driven by a drive signal to which a modulation signal is applied and a semiconductor optical amplifier (SOA). The high-power directly modulated laser has an optical absorption element between the directly modulated laser and the SOA. The directly modulated laser, the SOA, and the optical absorption element are monolithically integrated on one substrate.

### TECHNICAL FIELD

The present invention relates to a high-power directly modulated laser, and more particularly to a high-power directly modulated laser into which a directly modulated laser and an optical amplifier are integrated.

### BACKGROUND ART

A distributed feedback laser (DFB laser) or a distributed Bragg reflector laser (DBR laser), which is a directly modulated laser, has a narrow oscillation linewidth controlled by a diffraction grating and serves as an optical device suitable for high-density wavelength division multiplexing. In recent years, a higher transmission capacity has been desired along with an increase in communication traffic, and therefore the directly modulated laser is required to have an even higher modulation rate. On the other hand, at the same time the directly modulated laser is required to have a longer transmission distance and more branches to reduce costs of communication infrastructure facilities, and is also needed to have higher laser power. For common semiconductor lasers, the output power is dependent on the length of a resonator, and an optical device having a longer resonator is needed in order to increase the power.

However, a longer resonator leads to a higher junction capacitance of a semiconductor, which makes it difficult to achieve high-rate modulation. Thus, there is a trade-off relationship between the output power and the modulation rate. For this reason, an approach having been used to increase the power is to connect a semiconductor optical amplifier (SOA) to the output side of the directly modulated laser in cascade for optical amplification. To increase the power of the EA-DFB laser, into which a DFB laser and an electroabsorption (EA) optical modulator are integrated, a structure having an optical amplifier additionally integrated thereinto has been proposed (for example, see Patent Document 1).

FIG. 1 is a cross-sectional view in the optical axis direction of a conventional directly modulated laser having a DFB laser and an SOA integrated thereinto. A directly modulated laser 102 includes a DFB laser 121 and an SOA 123. The DFB laser 121 and the SOA 123 have respectively waveguide structures including waveguides (40, 42) for light confinement, and main functions of the components are converged into respective waveguide units. The LD waveguide 40 and the SOA waveguide 42 are optically connected to each other by a connection waveguide 43, and the light having propagated through the waveguides is output from a front waveguide output end 120. To increase the optical power emitted from the front waveguide output end 120, a rear waveguide output end 119 is provided with a highly reflective film 32. The front waveguide output end 120 is provided with a non-reflective film 31 to suppress return light.

The DFB laser 121 and the SOA 123, which are components of the directly modulated laser 102, are formed on one n-type InP substrate 38. In the waveguide structures, the lower clad is the n-type InP substrate 38, and the upper clad is a p-type InP layer 39. The refractive indexes of the upper and lower clads are designed to be lower than that of the waveguide core portion to achieve light confinement. For the components of the directly modulated laser 102, the positive electrodes are upper electrodes 33 and 35, and the ground is a lower electrode 36. The region of the upper surface of the directly modulated laser 102 excluding the electrodes is protected by an insulating film 37.

### CITATION LIST

### Patent Literature

Patent Literature 1: Japanese Patent Laid-Open No. 2013-258336

### SUMMARY OF THE INVENTION

### Technical Problem

One problem of the directly modulated laser having the DFB laser and the SOA integrated thereinto is laser oscillation (parasitic oscillation) in the SOA unit. A constant current is injected into the upper electrode 33 of the SOA 123, and a biased modulation current is injected into the upper electrode 34 of the DFB laser 121. When the modulation signal has a minimum value, the optical power output from the DFB laser 121 is low so that the stimulated emission in the SOA 123 is weak and carriers are accumulated in the active region. As a result, strong amplified spontaneous emission (ASE) is output from the SOA 123. The ASE emitted to the rearward of the SOA 123, that is in the −Z direction, is incident on the DFB laser 121. Due to the reflection by a diffraction grating in the DFB laser 121, part of the light returns to the SOA 123 again, which causes the SOA 123 to generate a laser oscillation.

To date, there is no optical isolator that can be monolithically formed on a semiconductor substrate together with a directly modulated laser and an SOA. Therefore, it is difficult, in the laser having the directly modulated DFB laser and the SOA integrated thereinto, to limit the light propagation direction to only one direction from the DFB unit to the SOA unit. Since the return of part of the light to the SOA 123 lowers the laser oscillation threshold in the SOA 123, a parasitic oscillation will occur when a current of a certain value or more is injected into the SOA 123.

FIG. 2 illustrates the IL characteristics of the conventional directly modulated laser. It represents the relationship (IL characteristics) between the injection current into the SOA 123 and the output power when the injection current is varied in the directly modulated laser 102. In this case, no drive current is passed through the DFB laser 121. The SOA length is 500 μm. A sharp increase in output power appears at an SOA current of about 92 mA, which indicates the occurrence of laser oscillation.

FIG. 3 illustrates optical spectrums in the vicinity of the oscillation threshold of the conventional directly modulated laser. At an injection current of 80 mA as shown in FIG. 3(a) (lower than the oscillation threshold), an oscillation spectrum including comb-shaped ripples appears. At an injection current of 100 mA as shown in FIG. 3(b) (greater than the oscillation threshold), one spectral peak occurring near a wavelength of 1497 nm is prominent compared to the other peaks, which indicates the occurrence of laser oscillation.

As shown in FIG. 3(b), since the output of the directly modulated laser is disturbed due to the multi-longitudinal mode oscillation in the wavelength range of optical communication, the directly modulated laser must be operated at or below the parasitic oscillation threshold of the SOA. Therefore, there is a problem such that the output power of the directly modulated laser is limited.

### Means for Solving the Problem

It is an object of the present invention to provide a high-power directly modulated laser in which oscillation of an SOA unit is suppressed.

To achieve the object, an embodiment of the present invention provides a high-power directly modulated laser that includes a directly modulated laser driven by a drive signal to which a modulation signal is applied and a semiconductor optical amplifier (SOA). The high-power directly modulated laser has an optical absorption element between the directly modulated laser and the SOA, and the directly modulated laser, the SOA, and the optical absorption element are monolithically integrated on one substrate.

### Effects of the Invention

According to the present invention, the optical absorption element provided between the directly modulated laser and the SOA allows the oscillation of the SOA to be suppressed, and the monolithic integration makes it possible to increase the power while maintaining compactness.

### BRIEF DESCRIPTION OF DRAWINGS

FIG. 1 is a cross-sectional view in the optical axis direction of a conventional directly modulated laser having a DFB laser and an SOA integrated thereinto.

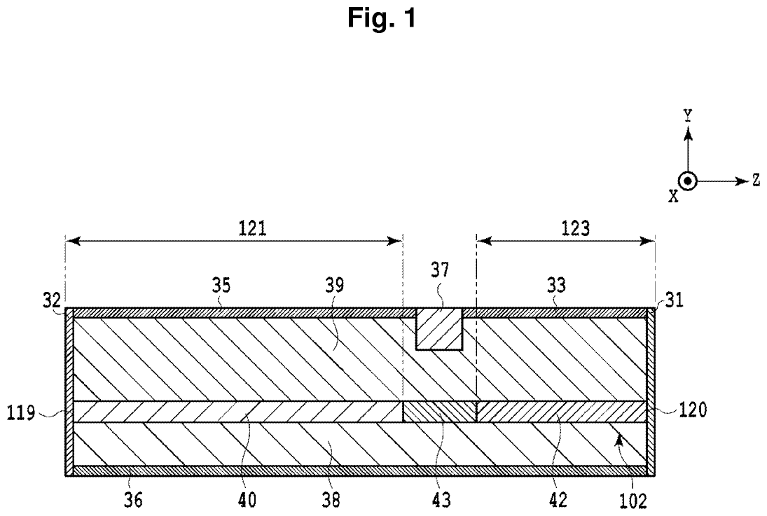

FIG. 2 illustrates IL characteristics of the conventional directly modulated laser.

FIG. 3 illustrates optical spectrums in the vicinity of an oscillation threshold of the conventional directly modulated laser.

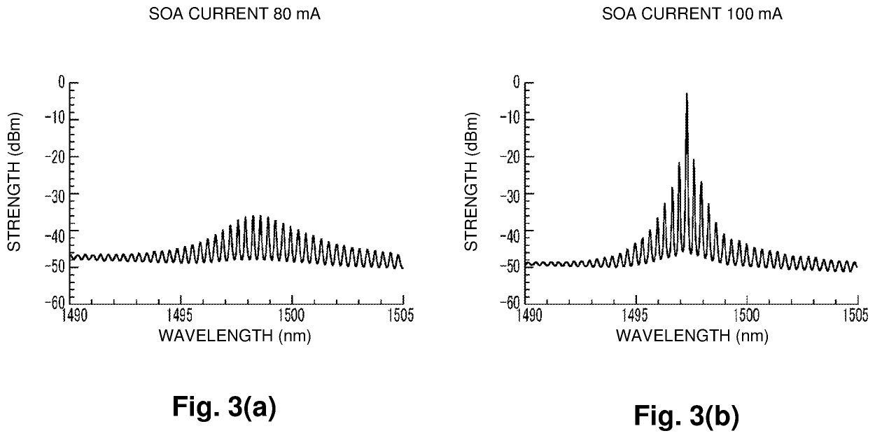

FIG. 4 is a bird's-eye view illustrating a structure of a high-power directly modulated laser according to an embodiment of the present invention.

FIG. 5 is a cross-sectional view in the optical axis direction of the high-power directly modulated laser according to the embodiment.

FIG. 6 illustrates IL characteristics of the high-power directly modulated laser according to the embodiment.

### DESCRIPTION OF EMBODIMENTS

Embodiments of the present invention will be described in detail below with reference to the accompanying drawings.

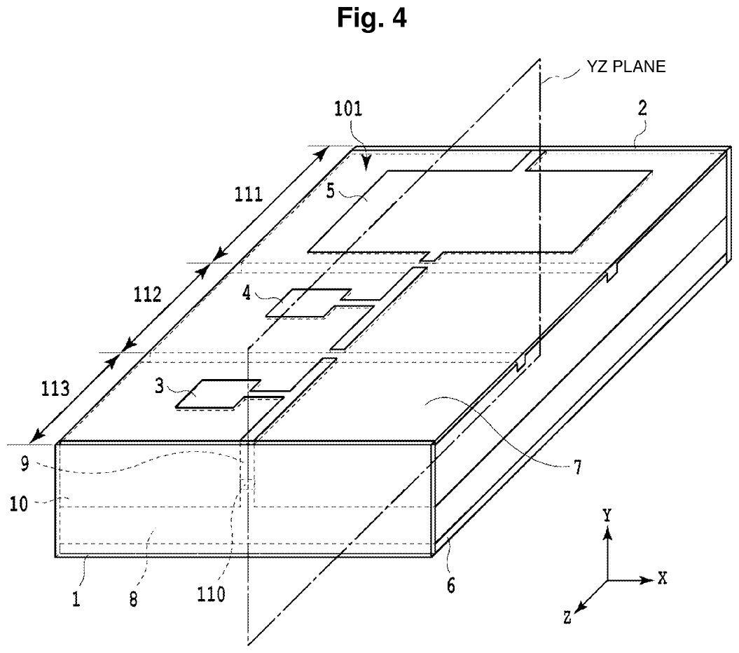

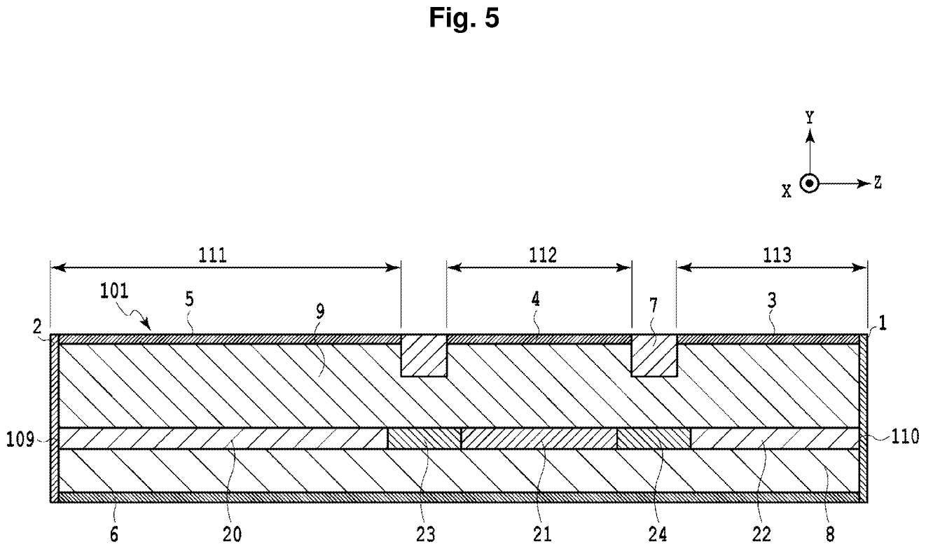

FIG. 4 illustrates a structure of a high-power directly modulated laser according to an embodiment of the present invention. FIG. 5 is a cross-sectional view of the YZ cross section, in the optical axis direction, of the high-power directly modulated laser. The high-power directly modulated laser 101 includes a directly modulated laser (LD) 111 driven by a drive signal to which a modulation signal is applied, as well as, on the emission end side of the LD 111, an electroabsorption attenuator (EA attenuator) 112 serving as an optical absorption element and a semiconductor optical amplifier (SOA) 113.

The LD 111 is a distributed feedback laser (DFB laser) or a distributed Bragg reflector laser (DBR laser) having a strained multi-quantum well (MQW) structure made of an InGaAsP-based or InGaAlAs-based material. The LD 111 outputs a wavelength in the wavelength range of optical communication (for example, a wavelength of 1570 nm). A DFB laser having a uniform diffraction grating is described as an example of the LD 111 according to the embodiment.

To increase the optical power emitted from a front waveguide output end 110, a rear waveguide output end 109 is provided with a highly reflective film 2. When the LD 111 is a DFB laser or a DBR laser in which a ¼λ shift structure is added to the diffraction grating, the highly reflective film 2 is replaced with a non-reflective film.

Although the material and the MQW structure of the active region of the SOA 113 are usually the same as those of the LD 111, the present invention is effective even when they are different.

The LD 111, the EA attenuator 112, and the SOA 113 have respectively waveguide structures including waveguides(20, 21, 22) for light confinement, and main functions of the components are converged into respective waveguide units. The LD waveguide 20, the EA attenuator waveguide 21, and the SOA waveguide 22 are optically connected to each other by connection waveguides 23 and 24. The light having propagated through the waveguides is output from the front waveguide output end 110. The front waveguide output end 110 is provided with a non-reflective film 1 to suppress return light. Although the components in FIG. 5 are each connected via the connection waveguides 23 and 24, they may bypass these optical waveguides and be directly connected to each other. The present invention is also effective when an additional waveguide structure, such as a spot size converter, is inserted between the output end and the highly reflective film 2 at the rear waveguide output end 109 or between the waveguide end and the non-reflective film 1 at the front waveguide output end 110.

The LD 111, the EA attenuator 112, and the SOA 113, which are the components of the high-power directly modulated laser 101, are monolithically integrated on one n-type InP substrate 8. The structure of the high-power directly modulated laser 101 in the XY cross section is a Buried Hetero (BH) structure. In the waveguide structures, the lower clad is the n-type InP substrate 8, and the upper clad is a p-type InP layer 9. The lateral clad is a buried and regrown Fe-added Semi-insulating (SI) layer 10 (shown in FIG. 4).

The refractive indexes of the upper and lower clads are designed to be lower than that of the waveguide core portion to achieve light confinement. For the components of the high-power directly modulated laser 101, the positive electrodes are upper electrodes 3, 4, and 5, and the ground is a lower electrode 6. The region of the upper surface of the high-power directly modulated laser 101 excluding the electrodes is protected by an insulating film 7.

The EA attenuator 112 serving as an optical absorption element has an MQW structure made of an InGaAsP-based or InGaAlAs-based material as with the LD 111. The amount of optical loss of the EA attenuator can be controlled by short-circuit, opening, or application of a bias voltage between the upper electrode 4 and the lower electrode 6.

According to the structures described above, when the ASE emitted from the SOA 113 to the LD 111 is reflected by the diffraction grating in the LD 111 and returns to the SOA 113 again, it moves back and forth in the EA attenuator 112. Therefore, a large loss can be caused to the light returning to the SOA 113, and the parasitic oscillation of the SOA can be suppressed.

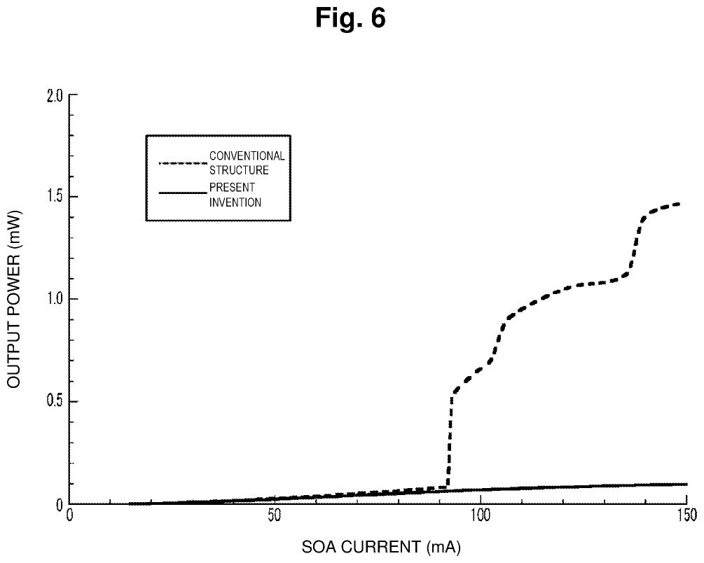

FIG. 6 illustrates IL characteristics of the high-power directly modulated laser according to the embodiment. It represents the relationship (IL characteristics) between the injection current into the SOA 113 and the output power when the injection current is varied in the high-power directly modulated laser 101. In this case, no drive current is passed through the LD 111. The upper electrode 4 and the lower electrode 6 of the EA attenuator 112 are short-circuited. The LD 111 has the same configuration as that of the conventional DFB laser 121 described above, and the power of the LD 111 is 4 mW at a wavelength of 1550 nm. The SOA length of the SOA 113 is 500 μm, which is also the same as that of the conventional DFB laser 121, and the gain of the SOA 113 is 10 dB. The length of the EA attenuator 112 is 100 μm. The amount of optical loss of the EA attenuator 112 can be controlled with a reverse bias voltage applied to the upper electrode 4, and when the applied voltage value is in a range of 0 to −2 V, a one-way loss of −1 to −10 dB is caused.

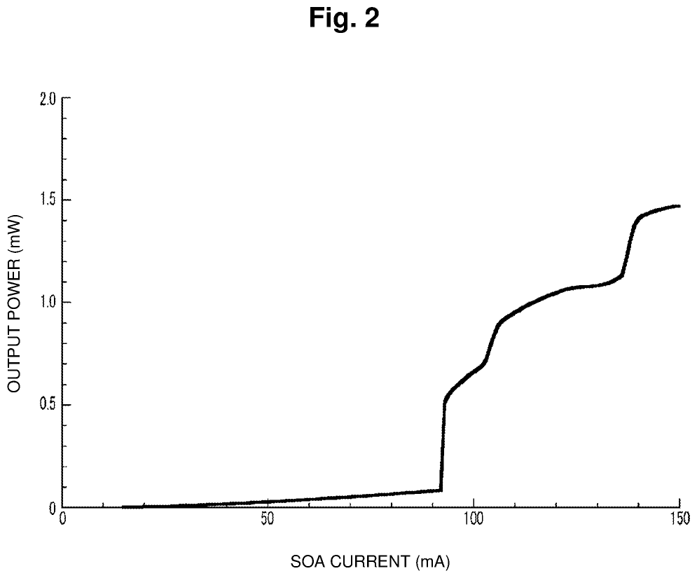

In FIG. 6, the result of FIG. 2 is added as a dotted line for comparison. Even when the current value to the SOA 113 is 100 mA or greater, no sharp output power fluctuation appears, which indicates the suppression of laser oscillation.

According to the embodiment, the EA attenuator 112 is provided between the LD 111 and the SOA 113, and consequently, even if the modulation signal has a minimum value when the injection current or the applied voltage of the LD 111 is directly modulated, the parasitic oscillation that may be caused in the SOA 113 can be suppressed.

### REFERENCE SIGNS LIST

1, 31 non-reflective film

2, 32 highly reflective film

3 to 5, 33, 35 upper electrode

6, 36 lower electrode

7, 37 insulating film

8, 38 n-type InP substrate

9, 39 p-type InP layer

10 SI layer

20, 40 LD waveguide

21 EA attenuator waveguide

22, 42 SOA waveguide

23, 24, 43 connection waveguide

101 high-power directly modulated laser

102 directly modulated laser

109, 119 rear waveguide output end

110, 120 front waveguide emission end

111 directly modulated laser (LD)

112 EA attenuator

113, 123 SOA

121 DFB laser

1. A high-power directly modulated laser including a directly modulated laser driven by a drive signal to which a modulation signal is applied and a semiconductor optical amplifier (SOA), comprising:
an optical absorption element between the directly modulated laser and the SOA,
wherein the directly modulated laser, the SOA, and the optical absorption element are monolithically integrated on one substrate.

2. The high-power directly modulated laser according to claim 1, wherein the optical absorption element is an electroabsorption attenuator (EA attenuator), and an amount of optical loss is controlled by short-circuit, opening, or application of a bias voltage between electrodes.

3. The high-power directly modulated laser according to claim 2, wherein the directly modulated laser, the optical absorption element, and the SOA have a same strained multi-quantum well (MQW) structure.

4. The high-power directly modulated laser according to claim 3, wherein the MQW structure made of an InGaAsP-based or InGaAlAs-based material is formed on an n-type InP substrate.
